(19) United States
(12) Patent Application Publication
(10) Pub. No.: US 2025/0374603 A1
(43) Pub. Date: Dec. 4, 2025

(54) JOG REDUCTION INTEGRATION FOR NANORIBBONS OF DIFFERENT WIDTHS

(71) Applicants: Xia Li, San Diego, CA (US); Charles Henry Wallace, Portland, OR (US); Leonard P. Guler, Hillsboro, OR (US); Marni Nabors, Portland, OR (US); Prashanth Aprameyan, San Jose, CA (US); Curtis Tsai, Beaverton, OR (US)

(72) Inventors: Xia Li, San Diego, CA (US); Charles Henry Wallace, Portland, OR (US); Leonard P. Guler, Hillsboro, OR (US); Marni Nabors, Portland, OR (US); Prashanth Aprameyan, San Jose, CA (US); Curtis Tsai, Beaverton, OR (US)

(21) Appl. No.: 18/733,113

(22) Filed: Jun. 4, 2024

(51) Int. Cl. H01L 29/423; H01L 27/088; H01L 29/06; H01L 29/08; H01L 29/66; H01L 29/775; H01L 29/786

(52) U.S. Cl. CPC H10D 30/6735; H10D 30/014; H10D 30/43; H10D 30/6757; H10D 62/118; H10D 62/151; H10D 64/017; H10D 84/83

(57) ABSTRACT

A row of gate-all-around (GAA) transistors include semiconductor channel regions, such as nanoribbons or nanosheets, of different widths. The semiconductor regions along the row are aligned at their centers, which may reduce the jog effect between semiconductor channels of different widths compared to side-aligned nanoribbons. A particular row of transistors may include channel regions of at least three different widths. The transistors may be arranged such that nanoribbons of a medium width are between nanoribbons of smaller and larger widths.

### BACKGROUND

Non-planar transistors are three-dimensional electronic devices that deviate from a traditional flat transistor design. Compared to planar transistors, non-planar transistors can provide improved control over current flow, reduced leakage, and enhanced performance, making it a key technology for smaller, faster, and more energy-efficient electronic devices. Examples of non-planar transistors include fin-shaped field-effect transistors, referred to as FinFETs, and gate-all-around (GAA) transistors. GAA transistors, also referred to as surrounding-gate transistors, have a gate material that surrounds a channel region on all sides.

Transistors may be designed with different shapes, configurations, or dimensions based on performance requirements, power consumption, density factors, or other considerations. For example, increasing the gate width of a transistor can enable the transistor to operate at a higher power, which can provide higher performance. However, increasing gate width increases the surface area used by transistors, which in turn reduces transistor density.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1A is a cross-section across a nanoribbon-based transistor showing the source, gate, and drain.

FIG. 1B is a cross-section of the nanoribbon-based transistor through the plane AA′ in FIG. 1A.

FIG. 1C is a cross-section through the plane CC′ in FIG. 1A, illustrating a set of nanoribbon-based transistors including the transistor of FIG. 1A.

FIG. 2A is a cross-section of a layout design for several transistors where different channel regions have different widths.

FIG. 2B illustrates jog effects the design of FIG. 2A.

FIG. 3 illustrates an example layout for reducing the jog effects illustrated in FIG. 2B.

FIG. 4A illustrates an example layout design for reducing the jog effects illustrated in FIG. 2B, according to some embodiments of the present disclosure.

FIG. 4B illustrates example jog effects of the design of FIG. 4A, according to some embodiments of the present disclosure.

FIG. 5A illustrates the example layout design of FIG. 4A with sources and drains formed along the nanoribbons, according to some embodiments of the present disclosure.

FIG. 5B illustrates example jog effects of the design of FIG. 5A, according to some embodiments of the present disclosure.

FIG. 6 illustrates an example layout design with reduced jog effects and three different nanoribbon widths, according to some embodiments of the present disclosure.

FIG. 7A illustrates an example implementation of the layout design of FIG. 6 with sources and drains formed along the nanoribbons and example jog effects, according to some embodiments of the present disclosure.

FIG. 7B illustrates an example implementation of the layout design of FIG. 6 with sources and drains formed along the nanoribbons and a variation of example jog effects, according to some embodiments of the present disclosure.

FIG. 8 illustrates an example layout design with reduced jog effects across multiple lines with different sets of widths, according to some embodiments of the present disclosure.

FIG. 9 illustrates an example implementation of the layout design of FIG. 8 with sources and drains formed along the nanoribbons and example jog effects, according to some embodiments of the present disclosure.

FIGS. 10A and 10B are top views of a wafer and a die, respectively, that include one or more rows of center-aligned nanoribbons with different widths in accordance with any of the embodiments disclosed herein.

FIG. 11 is a cross-sectional side view of an IC device that may include one or more rows of center-aligned nanoribbons with different widths in accordance with any of the embodiments disclosed herein.

FIG. 12 is a cross-sectional side view of an IC device assembly that may include one or more rows of center-aligned nanoribbons with different widths in accordance with any of the embodiments disclosed herein.

FIG. 13 is a block diagram of an example computing device that may include one or more rows of center-aligned nanoribbons with different widths in accordance with any of the embodiments disclosed herein.

### DETAILED DESCRIPTION

### Overview

The systems, methods and devices of this disclosure each have several innovative aspects, no single one of which is solely responsible for all desirable attributes disclosed herein. Details of one or more implementations of the subject matter described in this specification are set forth in the description below and the accompanying drawings.

For purposes of illustrating center-aligned nanoribbon transistors with different channel widths as described herein, it might be useful to first understand phenomena that may come into play in certain IC arrangements. The following foundational information may be viewed as a basis from which the present disclosure may be properly explained. Such information is offered for purposes of explanation only and, accordingly, should not be construed in any way to limit the broad scope of the present disclosure and its potential applications.

In integrated circuit (IC) devices, there is often a tradeoff between device size and device power or performance. For the past several decades, the scaling of features in ICs has been a driving force in the semiconductor industry. Scaling to smaller and smaller features enables increased densities of functional units on the limited real estate of semiconductor chips. For example, shrinking transistor size allows for the incorporation of an increased number of memory or logic devices on a chip, lending to the fabrication of products with increased capacity. The drive for the ever-increasing capacity, however, is not without issue. At smaller dimensions, the amount of power that can be driven through a transistor decreases, which can result in lower-performance devices, e.g., devices that operate at lower power and enable lower switching frequencies. For many applications, it is useful to have a mix of devices, e.g., some smaller, lower-power devices, and other larger, higher-power devices.

Transistors typically include a gate stack coupled to a semiconductor channel. As noted above, in a planar transistor, increasing the gate width of a transistor can enable the transistor to operate at a higher power, which can provide higher performance. Designs for non-planar transistors (e.g., FinFETs and GAA transistors) often have a fixed gate width. Instead of altering the gate width, the channel structure may be modified to create channel variation. For example, in FinFETs, multiple fins may be combined under a single gate to increase the amount of current that passes through a single transistor compared to single-fin transistors. In GAA transistors, channel material (e.g., nanoribbon stacks) of different widths, where channel width is perpendicular to the gate width, may be used to form transistors with different amounts of current and power flow.

In GAA transistors, stacks of channel material are arranged along multiple parallel rows. For example, rows of alternating n-type and p-type channels may be formed across a device region. Multiple transistors are formed along a particular row, with alternating gate and source/drain structures. In some cases, along a particular row, the channel material may have different widths, to provide the desired mix of transistors operating at different powers and offering different levels of performance. In previous implementations, along a row, nanoribbons of different widths were aligned along one side and staggered at the opposite side. While the nanoribbon layout may have sharp corners between sections of different widths, local layout effects (LLE) tend to round the corners in fabricated nanoribbons, which can create undesired variation in the widths of the nanoribbon channels. This is referred to as a jog effect.

The GAA transistors described herein include semiconductor channel regions (e.g., nanoribbons or nanosheets) of different widths along a row of transistors. The semiconductor regions along a particular row are aligned at their centers, which reduces the jog effect between semiconductor channels of different widths. In some embodiments, a row includes channel regions of at least three different widths. Widths may be, for example, between 1 and 4 nanoribbons apart, offering higher granularity than previous devices. In some cases, the nanoribbons are arranged such that nanoribbons of a medium width are between nanoribbons of smaller and larger widths, which can avoid a large change in width between neighboring transistors along a row. These design rules can further reduce the jog effect in an IC device.

The transistors described herein may be used in various applications. For example, for a dynamic random-access memory (DRAM) application, a transistor can be coupled to a capacitor. For a static random-access memory (SRAM) application, multiple transistors may be coupled together to form a single memory cell. The transistors described herein may also be used as computing or logic devices. In some embodiments, different transistors (e.g., transistors of different widths) may have different functions, e.g., higher-power transistors may be used as pull-up or pull-down transistors, while lower-power transistors are used as logic devices.

For purposes of explanation, specific numbers, materials and configurations are set forth in order to provide a thorough understanding of the illustrative implementations. However, it will be apparent to one skilled in the art that the present disclosure may be practiced without the specific details or/and that the present disclosure may be practiced with only some of the described aspects. In other instances, well known features are omitted or simplified in order not to obscure the illustrative implementations.

In the following detailed description, reference is made to the accompanying drawings that form a part hereof, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. The meaning of “a,” “an,” and “the” include plural references. The meaning of “in” includes “in” and “on.”

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. The terms “substantially,” “close,” “approximately,” “near,” and “about,” generally refer to being within +/−20% of a target value, unless specified otherwise. Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

In the following detailed description, various aspects of the illustrative implementations will be described using terms commonly employed by those skilled in the art to convey the substance of their work to others skilled in the art. For example, as used herein, a “logic state” of a ferroelectric memory cell refers to one of a finite number of states that the cell can have, e.g. logic states “1” and “0,” each state represented by a different polarization of the ferroelectric material of the cell. In another example, as used herein, a “READ” and “WRITE” memory access or operations refer to, respectively, determining/sensing a logic state of a memory cell and programming/setting a logic state of a memory cell. In other examples, the term “connected” means a direct electrical or magnetic connection between the things that are connected, without any intermediary devices, while the term “coupled” means either a direct electrical or magnetic connection between the things that are connected or an indirect connection through one or more passive or active intermediary devices. The term “circuit” means one or more passive and/or active components that are arranged to cooperate with one another to provide a desired function. In yet another example, a “high-k dielectric” refers to a material having a higher dielectric constant (k) than silicon oxide. The terms “oxide,” “carbide,” “nitride,” etc. refer to compounds containing, respectively, oxygen, carbon, nitrogen, etc.

In the following, some descriptions may refer to a particular S/D region or contact being either a source region/contact or a drain region/contact. However, unless specified otherwise, which region/contact of a transistor is considered to be a source region/contact and which region/contact is considered to be a drain region/contact is not important because, as is common in the field of FETs, designations of source and drain are often interchangeable. Therefore, descriptions of some illustrative embodiments of the source and drain regions/contacts provided herein are applicable to embodiments where the designation of source and drain regions/contacts may be reversed.

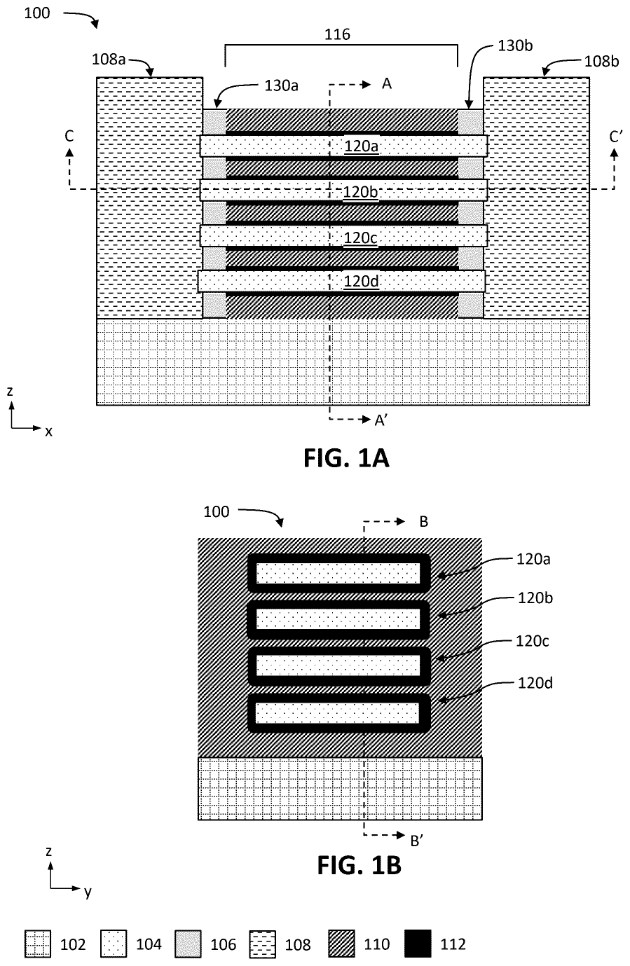

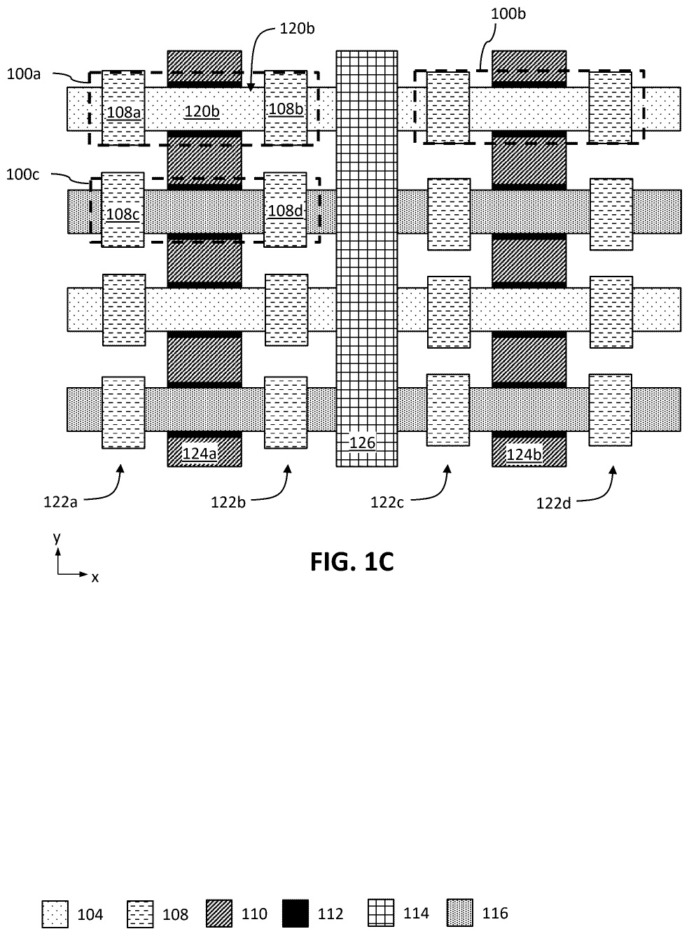

For convenience, if a collection of drawings designated with different letters are present, e.g., FIGS. 1A-1B, such a collection may be referred to herein without the letters, e.g., as “FIG. 1.”

### Example Nanoribbon Transistor

FIGS. 1A-1C illustrate an example architecture of a nanoribbon-based transistor. FIG. 1A is a cross-section across a transistor 100 showing the source, gate, and drain. FIG. 1B is a cross-section across the gate regions of the transistor 100. FIG. 1B is a cross-section through the plane AA′ in FIG. 1A, and FIG. 1A is a cross-section through the plane BB′ in FIG. 1B. FIG. 1C is a cross-section through the plane BB′ in FIG. 1A, illustrating a set of nanoribbon-based transistors including the transistor 100 of FIGS. 1A and 1B. The nanoribbon-based transistor 100 illustrates certain structures and materials that may be used in arrangements of nanoribbon transistors with different widths, discussed further below.

A number of elements referred to in the description of FIGS. 1-9, and with reference numerals are illustrated in these figures with different patterns, with a legend at the bottom of the page showing the correspondence between the reference numerals and patterns. The legend illustrates that FIGS. 1A and 1B use different patterns to show a support structure 102, a channel material 104, a dielectric material 106, a source or drain (S/D) region 108, a gate electrode 110, and a gate dielectric 112.

In the drawings, some example structures of various devices and assemblies described herein are shown with precise right angles and straight lines, but it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication.

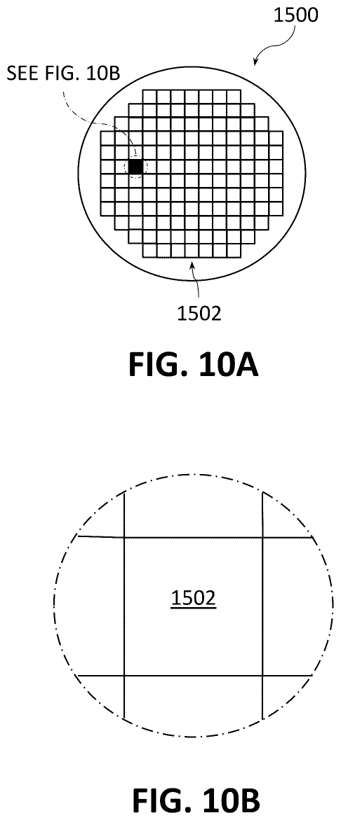

In general, implementations of the present disclosure may be formed or carried out on a support structure, e.g., the support structure 102 illustrated in FIG. 1. The support structure 102 may be, e.g., a substrate, a die, a wafer or a chip. For example, the support structure may be the wafer 1500 of FIG. 10A, discussed below, and may be, or be included in, a die, e.g., the singulated die 1502 of FIG. 10B, discussed below. The support structure 102 extends along the x-y plane in the coordinate system shown in FIG. 1. In some embodiments, a support structure 102 may be used during a fabrication process and later removed. For example, a top side of the transistor 100 may be attached to a second support structure (e.g., a second one of the support structures 102, which may be referred to as a carrier structure), and the support structure 102 over which the transistor 100 is formed may be removed to expose the back side of the transistor 100.

In some embodiments, a support structure may be a substrate that includes silicon and/or hafnium. More generally, the support structure may be a semiconductor substrate composed of semiconductor material systems including, for example, N-type or P-type materials systems. In one implementation, the semiconductor substrate may be a crystalline substrate formed using a bulk silicon or a silicon-on-insulator (SOI) substructure. In other implementations, the semiconductor substrate may be formed using alternate materials, which may or may not be combined with silicon, that include, but are not limited to, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-V materials (i.e., materials from groups III and V of the periodic system of elements), group II-VI (i.e., materials from groups II and IV of the periodic system of elements), or group IV materials (i.e., materials from group IV of the periodic system of elements). In some embodiments, the substrate may be non-crystalline. In some embodiments, the support structure may be a printed circuit board (PCB) substrate. Although a few examples of materials from which the substrate may be formed are described here, any material that may serve as a foundation upon which a semiconductor device including one or more nanoribbon transistors, as described herein, may be built falls within the spirit and scope of the present disclosure.

In FIGS. 1A and 1B, a transistor 100 is formed over a support structure 102. The transistor 100 includes a channel material 104 formed into four nanoribbons stacked on top of each other. In other examples, the transistor 100 may include more or fewer nanoribbons, e.g., one, two, three, five, six or more nanoribbons. The channel material 104 may be a semiconductor, such as silicon or other semiconductor materials described herein.

The transistor 100 includes nanoribbons 120a, 120b, 120c, and 120d, referred to collectively as nanoribbons 120 or individually as a nanoribbon 120. Each nanoribbon 120 is at a different height in the z-direction in the orientation shown in FIGS. 1A and 1B, i.e., a different distance from the support structure 102, where the nanoribbon 120a is the greatest distance from the support structure 102, and the nanoribbon 120d is the smallest distance from the support structure 102. S/D regions 108a and 108b are formed at either end of the nanoribbon channels 120, as illustrated in FIG. 1A.

The nanoribbons 120 may be any three-dimensional semiconductor structures around which the memory cells described herein may be formed, including, for example, nanowires with a square or circular cross-section, or nanosheets with a wider rectangular cross section. The term nanosheet is sometimes used to highlight the relative breadth and thinness of a particular nanoribbon structure. For example, the term nanosheet may indicate that a structure has a small height (in the z-direction in the example coordinate system) and a broader width (into the page in FIG. 1A, i.e., in the x-direction in the coordinate system shown) compared to other nanostructures, like nanowires. In other embodiments, the nanoribbons 120 may have cross-sections that are squares with rounded corners, rectangles with rounded corners, ovals, or other shapes. In some embodiments, the nanoribbons 120 are coupled on one side (e.g., on the right side in the orientation shown in FIG. 1B) to a dielectric fin, and another set of nanoribbons extend from the opposite side of the dielectric fin, thus forming a forksheet arrangement.

In general, to form nanoribbon channels such as the nanoribbon channels 120, alternating layers of the channel material 104 and a sacrificial material are deposited over the support structure 102. The sacrificial material is removed from the stack and replaced with other material, e.g., material for forming a gate stack, so the sacrificial material is not shown in FIG. 1. The channel material 104 and sacrificial materials include different materials. In one example, the channel material 104 is silicon, while the sacrificial material includes silicon and germanium. The sacrificial material may be chosen to have a similar crystal structure to the channel material 104, so that monocrystalline layers of the channel material 104 (or substantially monocrystalline layers, e.g., with a crystal size of at least 5 nanometers, at least 20 nanometers, at least 50 nanometers, or at least 100 nanometers) and monocrystalline layers of the sacrificial material (or substantially monocrystalline layers) may be formed over each other. In different embodiments, the channel material 104 and/or the sacrificial material may be formed of any suitable single-crystal material, such as sapphire, quartz, silicon, a compound of silicon (e.g., silicon oxide), indium phosphide, germanium or a germanium alloy (e.g., silicon germanium), gallium, arsenic (e.g., an arsenide III compound, where arsenic III is in combination with another element such as boron, aluminum, gallium, or indium), or any group III-V material (i.e., materials from groups III and V of the periodic system of elements).

More generally, the channel material 104 may be composed of semiconductor material systems including, for example, N-type or P-type materials systems. The channel material 104 may include a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. The channel material 104 may include one or more of cobalt oxide, copper oxide, ruthenium oxide, nickel oxide, niobium oxide, copper peroxide, indium telluride, molybdenite, molybdenum diselenide, tungsten diselenide, tungsten disulfide, molybdenum disulfide, N- or P-type amorphous or polycrystalline silicon, monocrystalline silicon, germanium, indium arsenide, indium gallium arsenide, indium selenide, indium antimonide, zinc antimonide, antimony selenide, silicon germanium, gallium nitride, aluminum gallium nitride, indium phosphite, black phosphorus, zinc sulfide, indium sulfide, gallium sulfide, each of which may possibly be doped with one or more of gallium, indium, aluminum, fluorine, boron, phosphorus, arsenic, nitrogen, tantalum, tungsten, and magnesium, etc.

In some cases, multiple channel materials may be included within an IC device. For example, an IC device may include both N-type metal-oxide-semiconductor (NMOS) transistors and P-type MOS (PMOS) transistors, e.g., alternating rows of NMOS and PMOS transistors. NMOS and PMOS logic can use different groups of channel material 104, e.g., silicon may be used to form an N-type semiconductor channel, while silicon germanium may be used to form a P-type semiconductor channel. In some cases, a single channel material 104 is used (e.g., silicon), and different portions (e.g., channel material to form different transistors) may include different dopants, e.g., N-type dopants for NMOS transistors and P-type dopants for PMOS transistors.

The S/D regions 108 may be formed from one or more layers of doped semiconductors, metals, metal alloys, or other materials. For example, the S/D regions 108 may include a doped semiconductor, such as silicon or another semiconductor doped with an N-type dopant or a P-type dopant. The S/D regions 108 may include multiple layers with different levels of conductivity, e.g., a doped semiconductor followed by a more highly doped semiconductor, or a semiconductor followed by metal.

A central portion of each of the nanoribbon channels 120 is surrounded by a gate stack, which in this example, includes a gate electrode 110 and gate dielectric 112. Nanoribbon transistors often include a gate dielectric that surrounds the nanoribbon channels 120, and a gate electrode that surrounds the gate dielectric. While not specifically shown, in some cases, the gate dielectric 112 around each nanoribbon channel 120 includes multiple layers, e.g., an oxide layer and a high-k dielectric layer. The oxide layer may be grown directly on the nanoribbon channels 120, and the high-k dielectric may surround the oxide. The oxide may include oxygen in combination with the channel material 104. For example, if the nanoribbon channels are formed from silicon, the gate dielectric 112 may include a layer of silicon oxide. The high-k dielectric may be formed over the oxide. The gate electrode 110 surrounds the gate dielectric 112, e.g., the high-k dielectric (if included). In this example, the gate electrode 110 is above and below the nanoribbon stack, and between adjacent nanoribbons 120.

The gate electrode 110 includes a conductive material, such as a metal. The gate electrode 110 may include at least one P-type work function metal or N-type work function metal, depending on whether the transistor 100 is a PMOS transistor or an NMOS transistor. For a PMOS transistor, metals that may be used for the gate electrode 110 may include, but are not limited to, ruthenium, palladium, platinum, cobalt, nickel, and conductive metal oxides (e.g., ruthenium oxide). For an NMOS transistor, metals that may be used for the gate electrode 110 include, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide). The gate electrode 110 may include a stack of two or more metal layers, where one or more metal layers are work function metal layers and at least one metal layer is a fill metal layer.

The gate dielectric 112 may include one or more high-k dielectric materials and may include elements such as hafnium, silicon, oxygen, titanium, tantalum, lanthanum, aluminum, zirconium, barium, strontium, yttrium, lead, scandium, niobium, and zinc. Examples of high-k materials that may be used include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate. The gate dielectric 112 may have a thickness between about 0.5 nanometers and 3 nanometers, including all values and ranges therein, e.g., between about 1 and 3 nanometers, or between about 1 and 2 nanometers.

Regions of the transistor 100 outside of the nanoribbons 120, gate stack, and S/D regions 108 are filled in with a dielectric material 106. In the region between the gate stack and the S/D regions 108, the dielectric material 106 forms a series of cavity spacers 130a and 130b. Cavity spacers 130, also referred to as “dimple spacers” or “inner spacers,” provide electrical isolation between the S/D regions 108 formed at the ends of the nanoribbons and the gate electrode 110 deposited around the nanoribbons 120.

FIGS. 1A and 1B illustrate a single nanoribbon transistor 100. In IC devices, many similar or identical transistors are arranged within a transistor layer, e.g., as illustrated in FIG. 1C. The dielectric material 106 and/or different dielectric materials may provide isolation between different transistors, or between other conductive materials in or near the transistor layer.

FIG. 1C is a cross-section through the plane BB′ in FIG. 1A, illustrating a set of nanoribbon-based transistors including the transistor of FIG. 1A. FIG. 1C illustrates a cross-section through multiple coplanar semiconductor regions, i.e., through multiple nanoribbons 120 of different stacks. For example, the transistor 100a in FIG. 1C corresponds to the transistor 100 in FIGS. 1A and 1B. The transistor 100a includes the S/D regions 108a and 108b and the nanoribbon 120b. The nanoribbon 120b extends in the x-direction in the coordinate system shown, e.g., into the transistor 100b, which is similar to the transistor 100a. Additional nanoribbons are arranged in rows below the nanoribbon 120b. The area shown in FIG. 1C has alternating rows of the channel material 104 and a second channel material 116. The channel material 116 may be any of the materials described above with respect to the channel material 104. In some embodiments, the channel materials 104 and 116 are the same material, and in other embodiments, the channel materials 104 and 116 are different materials. The channel materials 104 and 116 may be selected so that one channel materials (e.g., 104) is n-type and the other channel material (e.g., 116) is p-type, or vice versa. In some cases, the channel materials 104 and 116 may include different dopants to provide channels with different carrier types (i.e., n-type and p-type).

For example, the transistor 100c is a transistor with a different carrier type from the transistor 100a. Like the transistor 100a, the transistor 100c includes two S/D regions 108c and 108d. The S/Ds 108 are arranged along S/D lines, including S/D line 122a (which includes S/D regions 108a and 108c), 122b (which includes S/D regions 108b and 108d), 122c, and 122d. A first gate line 124a extends across multiple rows of transistors, including the transistors 100a and 100c. A second gate line 124b extends in parallel to the gate line 124a. The gate lines 124 include the gate electrode 110 and gate dielectric 112 described above. In some embodiments, a single gate line may include different materials, e.g., different gate dielectrics 112 and/or different gate electrode materials, e.g., different work function metals at transistors of different carrier types. In some embodiments, different gate lines may include different materials from each other.

An isolation region 126 is between the S/D lines 122b and 122c. The isolation region 126 may include one or more dielectric materials 114, such as oxides (e.g., aluminum oxide, hafnium oxide, silicon oxide, etc.), nitrides (e.g., silicon nitride), or any other dielectric material described herein. The isolation region 126 may also be referred to as a dummy gate, because in the pattern of gates and source/drain regions, the isolation region 126 is in the position of a gate (i.e., between a pair of S/D regions).

In this example, the isolation region 126 extends across multiple rows of nanoribbons (here, four nanoribbons), and the gate lines 124a and 124b also extend across multiple rows of nanoribbons. In other examples, isolation regions and/or gate lines may be shorter in the y-direction, e.g., extending across one or two nanoribbons. For example, along a particular gate line, isolation regions including the dielectric material 114 may be interspersed with gate stacks (including the gate dielectric 112 and gate electrode 110).

Example Transistors with Different Channel Widths

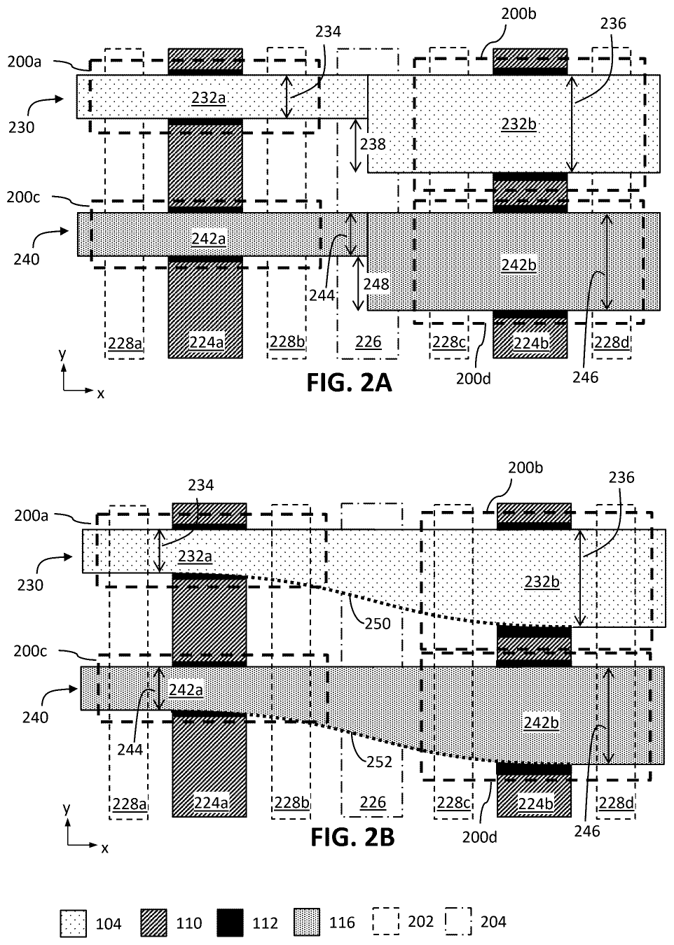

FIGS. 2A and 2B illustrate a design for transistors where different channel regions have different widths. FIG. 2A provides a layout plan, and FIG. 2B illustrates jog effects that may occur when the layout plan of FIG. 2A is fabricated. FIGS. 2A and 2B are cross-sections through the x-y plane, similar to the cross-section shown in FIG. 1C. While FIGS. 2A and 2B illustrate cross-sections through one layer of a set of nanoribbon transistors, the transistors may include a set of similar nanoribbons that are stacked in the z-direction, as shown in FIGS. 1A and 1B.

FIG. 2A illustrates one row 230 of the channel material 104 and one row 240 of the channel material 116. Row 230 includes a first channel region 232a having a first width 234 and a second channel region 232b having a second width 236. Row 240 includes a first channel region 242a having a first width 244 and a second channel region 242b having a second width 246. As depicted, the first widths 234 and 244 may be similar, and the second widths 236 and 246 may be similar.

FIG. 2A further includes two gate lines 224a and 224b, which are similar to gate lines 124a and 124b of FIG. 1C. FIG. 2A includes four S/D lines 228a, 228b, 228c, and 228d; the S/D regions that may be formed along the S/D lines 228 are not shown in FIG. 2A and in several subsequent figures, to illustrate the geometry of the channel materials more clearly. FIG. 2A also includes a dummy gate line 226, which corresponds to the isolation region 126; the region outlined by the dummy gate line 226 may be replaced by the dielectric material 114, forming an isolation region.

FIG. 2A further includes outlines around four transistors 200a, 200b, 200c, and 200d. Transistors 200a and 200c include channel regions 232a and 242a with relatively narrow widths 234 and 244. Transistors 200a and 200c may be relatively lower power transistors, with a low amount of current flowing across the relatively small channel regions 232a and 242a. Transistors 200b and 200d include channel regions 232b and 242b having widths 236 and 246, which are larger than the widths 234 and 244 of the channel regions 232a and 242a. Transistors 200b and 200d may be relatively higher power transistors, with a greater amount of current flowing across the relatively wider channel regions 232b and 242b.

In FIG. 2A, the channel regions 232a and 232b are aligned along their top edges (in the orientation of FIG. 2), and the channel regions 242a and 242b are aligned along their top edges. The difference in the widths 234 and 236 causes the channel region 232b to extend downward in the y-direction by a distance of 238, e.g., the lower edge of the channel region 232b is offset from the lower edge of the channel region 232a by a distance of 238, which is equal to the difference between the widths 236 and 234. Similarly, the channel region 242b extends downward in the y-direction by a distance of 248, which is the difference between the widths 246 and 244. In FIG. 2A, the channel regions 232a, 232b, 242a, and 242b are rectangular, with sharp corners. In a fabrication process, it may not be possible to achieve the rectangular shapes shown in FIG. 2A. Instead, a produced device may have rounded corners between channel regions of different widths.

FIG. 2B illustrates jog effects the design of FIG. 2A. FIG. 2B includes the features of FIG. 2A, described above. However, while the channel regions 232a, 232b, 242a, and 242b are illustrated with sharp corners at the boundary between channel regions 232a and 232b and the boundary between channel regions 242a and 242b, in FIG. 2B, a curved line 250 extends between the channel regions 232a and 232b and a curved line 252 extends between the channel regions 242a and 242b. Rather than a sharp increase in width from 234 to 236 at the boundary between channel regions 232a and 232b in row 230, the width of the channel material 104 in row 230 gradually increases from 234 to 236. Likewise, rather than a sharp increase in width from 244 to 246 at the boundary between channel regions 242a and 242b in row 240, the width of the channel material 116 in row 240 gradually increases from 244 to 246.

Within the transistor 200a, the width of the channel region 232a between the two S/D lines 228a and 228b increases moving left to right, i.e., the lower edge of the channel region 232a bends along the curve 250. Within the transistor 200b, the width of the channel region 232b between the two S/D lines 228c and 228d decreases moving right to left, with the lower edge of the channel region 232b bending along the curve 250. Similar effects are present along row 240. The inconsistent widths in the channel regions can lead to undesired electrical effects within the transistors.

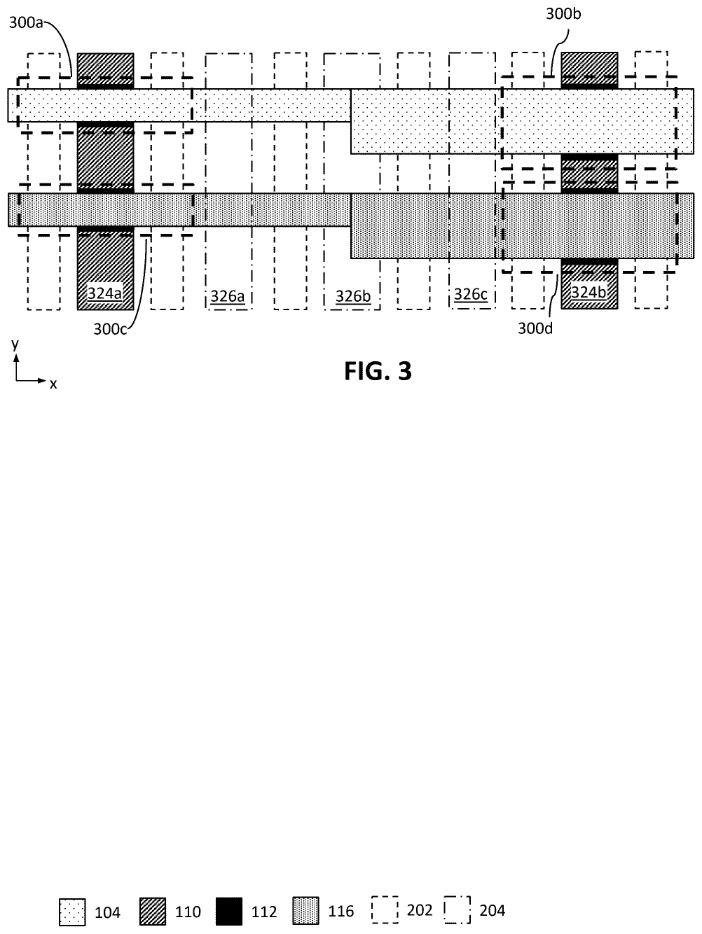

FIG. 3 illustrates one example arrangement for reducing the jog effects in FIG. 2B. In the example shown in FIG. 3C, a gate line (e.g., the gate line 224b) is replaced with another dummy gate 326b, such that adjacent gate lines 324a and 324b have three dummy gates 326a, 326b, and 326c between them. Said another way, there are three dummy gates 326a-326c between adjacent transistors in the x-direction (e.g., between transistors 300a and 300b, and between transistors 300c and 300d). While the additional separation in the x-direction reduces the jog effect on individual transistors, this layout greatly reduces transistor density across an area, which is undesirable.

Example Transistors with Different Channel Widths and Reduced Jog Effects

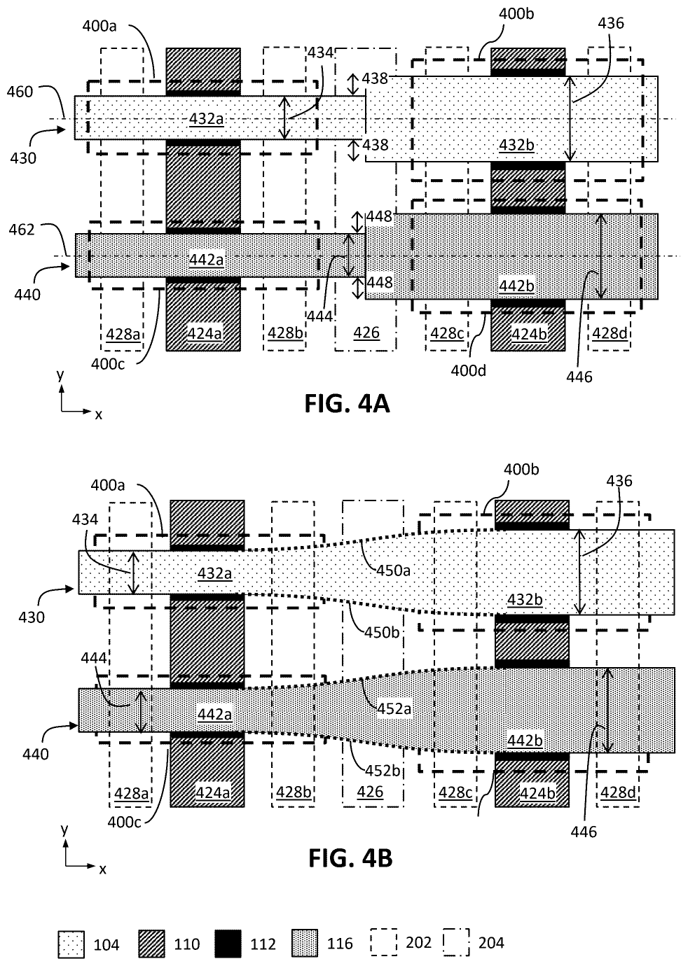

FIG. 4A illustrates an example layout design for reducing the jog effects of the design of FIG. 2A and FIG. 2B, according to some embodiments of the present disclosure. FIG. 4A includes similar features to FIG. 2A, including a first row 430 of the channel material 104 and a second row 440 of the channel material 116. The first row 430 includes a first channel region 432a having a first width 434 and a second channel region 432 having a second width 436. The second row 440 includes a first channel region 442a having a first width 444 and a second channel region 442b having a second width 446. As depicted, the first widths 434 and 444 may be similar, and the second widths 436 and 446 may be similar.

FIG. 4A further includes two gate lines 424a and 424b, which are similar to gate lines 124a and 124b of FIG. 1C, and to gate lines 224a and 224b of FIG. 2A. FIG. 4A includes four S/D lines 428a, 428b, 428c, and 428d, which are similar to the S/D lines 228 of FIG. 2A. FIG. 4A also includes a dummy gate line 426, which is similar to the dummy gate line 226 of FIG. 2A.

FIG. 4A includes outlines around four transistors 400a, 400b, 400c, and 400d. Transistors 400a and 400c include channel regions 432a and 442a with relatively narrow widths 434 and 444. Transistors 400a and 400c may be relatively lower power transistors, with a low amount of current flowing across the relatively small channel regions 432a and 442a. Transistors 400b and 400d include channel regions 432b and 442b having widths 436 and 446, which are larger than the widths 434 and 444 of the channel regions 432a and 442a. Transistors 400b and 400d may be relatively higher power transistors, with a greater amount of current flowing across the relatively wider channel regions 432b and 442b.

As described with respect to FIG. 2, while FIG. 4A illustrates cross-sections through one layer of a set of the transistors 400, the transistors 400 may include a set of similar nanoribbons that are stacked in the z-direction, as shown in FIGS. 1A and 1B. FIG. 4B and FIGS. 5-9 also illustrate cross-sections through the x-y plane, and the devices illustrated therein may similarly include multiple layers of channel material stacked in the z-direction, as shown in FIGS. 1A and 1B.

In FIG. 2A, channel regions along a given row 230 or 240 are aligned along one side, which resulted in the large curves 250 and 252 along the opposite sides of the channel regions, as shown in FIG. 2B and described above. In FIG. 4A, channel regions along a given row are aligned along a center line, resulting in a lower change in width at either side. For example, in row 430, the channel regions 432a and 432b are centered along a midline 460. Said another way, a central axis through each of the channel regions 432a and 432b is along the midline 460. The midline 460 extends perpendicular to the widths 434 and 436 of the channel regions 432. Similarly, in row 440, the channel regions 442 are centered along the midline 462, which is perpendicular to the widths 444 and 446.

By aligning the channel regions along their central axes, rather than the large jumps in width 238 and 248 at one side of the nanoribbons, as shown in FIG. 2A, the jumps in width at the edges of the channel regions are relatively small. Along row 430, a distance 438 extending in the y-direction is between top edges of the adjacent channel regions 432a and 432b, and the same distance 438 is between the bottom edges of the adjacent channel regions 432a and 432b. Along row 440, a distance 448 extending in the y-direction is between top edges of the adjacent channel regions 442a and 442b, and the same distance 448 is between the bottom edges of the adjacent channel regions 442a and 442b. The distances 438 and 448 may be smaller than the distances 238 and 248; for example, if the widths 234 and 434 are the same, and the widths 236 and 436 are the same, the distance 438 is half of the distance 238.

In FIG. 4A, the channel regions 432a, 432b, 442a, and 442b are rectangular, with sharp corners. In a fabrication process, it may not be possible to achieve the rectangular shapes shown in FIG. 4A. Instead, a produced device may have rounded corners between adjacent channel regions of different widths, as noted above.

FIG. 4B illustrates jog effects the design of FIG. 4A. FIG. 4B includes the features of FIG. 4A, described above. However, while the channel regions 432a, 432b, 442a, and 442b are illustrated with sharp corners at the boundary between channel regions 432a and 432b and the boundary between channel regions 442a and 442b, in FIG. 4B, curved lines 450a and 450b extend between the channel regions 432a and 432b, and curved lines 452a and 452b extend between the channel regions 442a and 442b. Rather than a sharp increase in width from 434 to 436 at the boundary between channel regions 432a and 432b in row 430, the width of the channel material 104 in row 430 gradually increases from 434 to 436. Likewise, rather than a sharp increase in width from 444 to 446 at the boundary between channel regions 442a and 442b in row 440, the width of the channel material 116 in row 440 gradually increases from 444 to 446.

Within the transistor 400a, the channel region 432a between the two S/D lines 428a and 428b is substantially rectangular, without the degree of bending shown in FIG. 2B due to the greater width increase (e.g., the distance 238) between adjacent channel regions. The channel regions 432b, 442a, and 442b are also more substantially rectangular than their counterparts in FIG. 2B. Reducing the inconsistency in widths within the channel regions 432 and 442 in the channel regions can mitigate the undesired electrical effects compared to the design of FIG. 2.

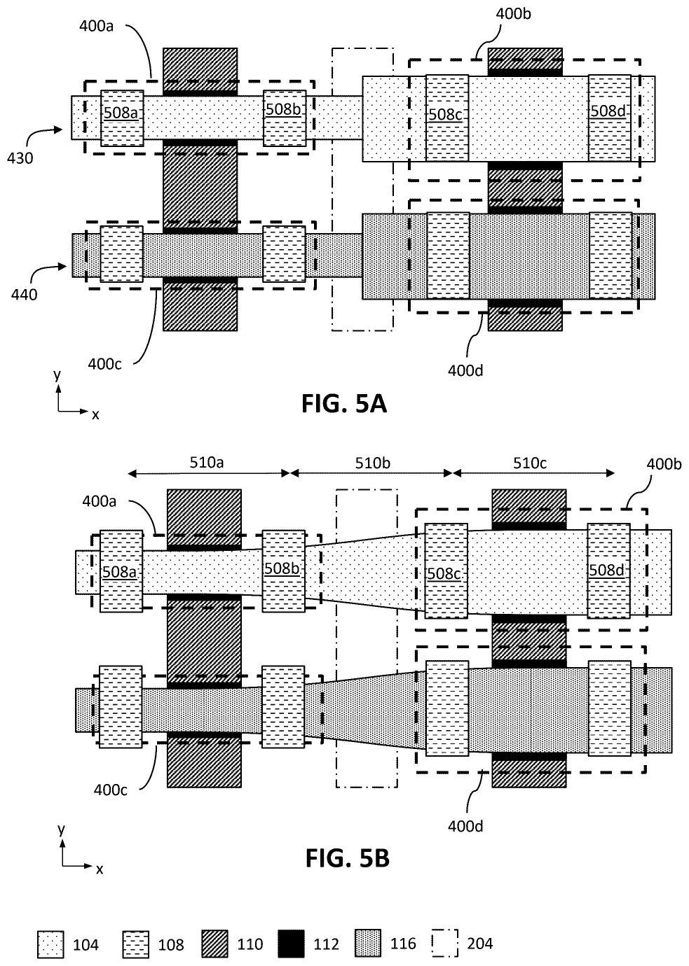

FIG. 5A illustrates the example layout design of FIG. 4A with sources and drains formed along the nanoribbons, according to some embodiments of the present disclosure. FIG. 5A illustrates the transistors 400a, 400b, 400c, and 400d of the layout design of FIG. 4A, discussed above. In FIG. 5A, rather than illustrating the S/D lines 428, S/D regions are shown, e.g., the S/D regions 508a and 508b for the transistor 400a, and the S/D regions 508c and 508d for the transistor 400b. The S/D regions 508 may replace portions of the channel materials 104 and 116. While the same S/D material 108 is shown along row 430 and row 440 (e.g., along rows of channel materials with different carrier types), in some embodiments, a different S/D material is used along the channel material 116. The S/D material 108 may be epitaxially grown. S/D contacts may be coupled to the S/D regions 508 to apply different charges to different S/D regions.

FIG. 5B illustrates example jog effects of the design of FIG. 5A, according to some embodiments of the present disclosure. FIG. 5B includes the features of FIG. 5A, including the S/D regions 508, but in FIG. 5B, curved lines (e.g., the curved lines 450 and 452, described with respect to FIG. 4B) illustrate example jog effects that may occur during fabrication of the design shown in FIG. 5A. FIG. 5B also illustrates example distances between adjacent S/D regions 508. FIG. 5B illustrates a distance 510a between the S/D regions 508a and 508b of transistor 400a, a distance 510b between the S/D regions 508b and 508c of adjacent transistors 400a and 400b, and a distance 510c between the S/D regions 508c and 508d of transistor 400b. Each of the distances 510a, 510b, and 510c may be equal. This may be contrasted to the example of FIG. 3, where the distance between S/D regions or S/D lines of adjacent transistors (e.g., between transistors 300a and 300b) was twice as long as the distance between S/D regions or S/D lines within a transistor.

Example Transistors with Three Channel Widths and Reduced Jog Effects

In the example of FIGS. 2-5, only two different channel widths were shown along a given row of channel material. In other embodiments, three or more different channel widths may be included in a row of channel material. For example, if the width 434 is a narrow width and the width 436 is a wide width, a medium width that is between the widths 434 and 436 may be added. By placing a channel region of medium width between channel regions of the wide width and wide width, the difference in widths between adjacent channel regions is reduced, further mitigating jog effects in the fabricated transistors. More generally, adding additional width granularity between the widest and narrowest width along a row of channel regions can, in coordination with design or placement rules, reduce jog effects and increase width regularity/consistency within transistor channel regions.

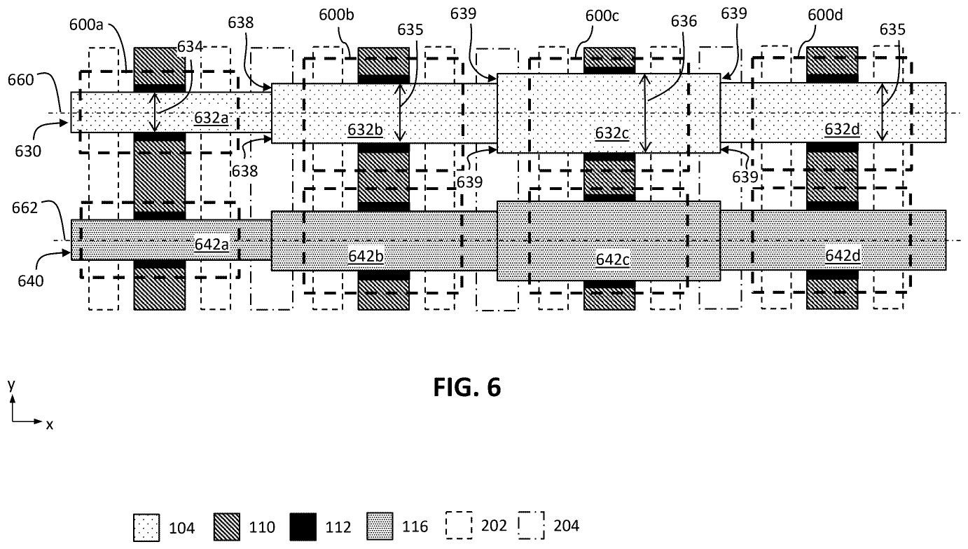

FIG. 6 illustrates an example layout design with reduced jog effects and three different nanoribbon widths, according to some embodiments of the present disclosure. Like FIG. 4A, FIG. 6 illustrates two rows 630 and 640 of the channel materials 104 and 116, respectively. Each row 630 and 640 includes four channel regions 632 or 642, e.g., row 630 includes channel regions 632a, 632b, 632c, and 632d. The centers of the channel regions along a given row are aligned along a midline, e.g., the channel regions 632 are centered on the midline 660, and the channel regions 642 are centered on the midline 662, in a similar manner to the channel regions 432 and 442 being center aligned on the respective midlines 460 and 462, discussed above.

Each channel region has a respective width, where width is measured in the y-direction, perpendicular to the midlines 660 and 662. The channel region 632a has a first width 634, the channel region 632b has a second width 635, the channel region 632c has a third width 636, and the channel region 632d has the second width 635. The channel region 632b is between the channel regions 632a and 632c, and the second width 635 is between the first width 634 and the third width 636. The channel regions 642 may have corresponding widths, e.g., the channel region 642a has the same width as the channel region 632a, etc.

A distance 638 extends in the y-direction is between top edges of the adjacent channel regions 632a and 632b, and the same distance 638 is between the bottom edges of the adjacent channel regions 632a and 632b. A distance 639 extends in the y-direction is between top edges of the adjacent channel regions 632b and 632c, and the same distance 639 is between the bottom edges of the adjacent channel regions 632b and 632c. Because the channel regions 632b and 632d have the same width 635 and are both center-aligned with the channel region 632c, the same distance 639 is also between top edges of the adjacent channel regions 632c and 632d and between the bottom edges of the adjacent channel regions 632c and 632d. Because row 630 has a third width 635 that is between the maximum and minimum widths 636 and 634, respectively, the distances 638 and 639 may each be smaller than the distance 438 of FIG. 4A.

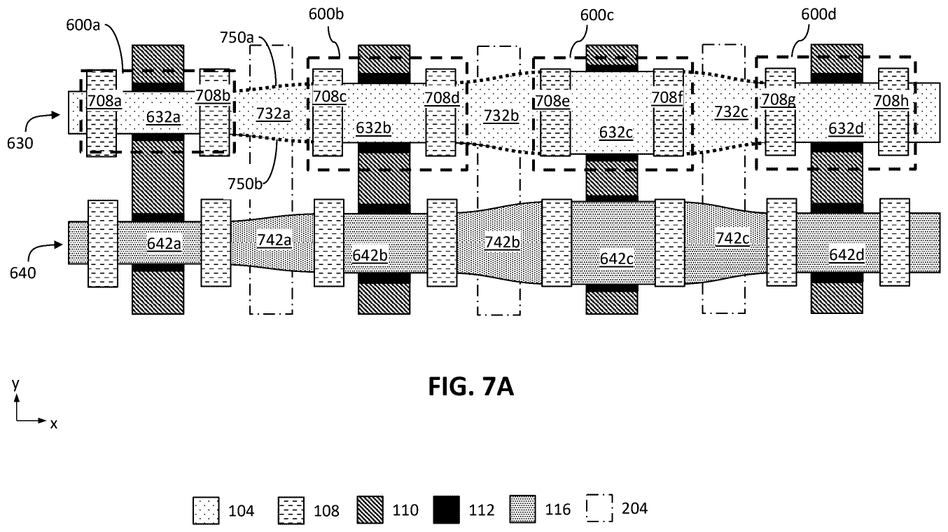

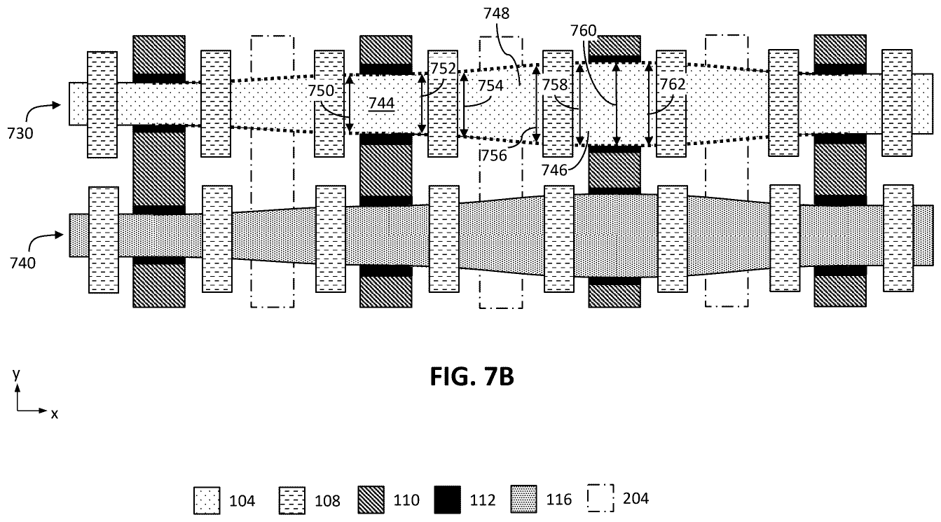

FIG. 7A illustrates an example implementation of the layout design of FIG. 6 with sources and drains formed along the nanoribbons and example jog effects, according to some embodiments of the present disclosure. FIG. 7A includes S/D regions 708a-708h along row 630 and similar S/D regions along row 640. The S/D regions 708 may be similar to the S/D regions 508, described above. The spacing between S/D regions within transistors may match spacing of S/D regions between adjacent transistors, as described with respect to FIG. 5B.

The S/D regions 708 separate portions of the channel regions 632 within each transistor from other areas of the channel material that remain between adjacent transistors. For example, the channel region 632a is the portion of the channel material 104 within the transistor 600a and between the S/D regions 708a and 708b, and the channel region 632b is the portion of the channel material 104 within the transistor 600b and between the S/D regions 708c and 708d. Another portion of the channel material 104, referred to as a semiconductor region 732a, is between the transistors 600a and 600b, and between the S/D regions 708b and 708c. Similar semiconductor regions 732b and 732c are between other adjacent pairs of transistors along row 630, while semiconductor regions 742a-742c formed from the channel material 116 are between pairs of adjacent transistors along row 640.

While the channel regions 632 and 642 in FIG. 6 are illustrated with sharp corners at the boundary between adjacent channel regions, in FIG. 7A, curved lines, illustrated with the dashed lines at the boundaries of the semiconductor regions 732 and 742, extend between adjacent channel regions, along the semiconductor regions 732 and 742. For example, the curved lines 750a and 750b are along the edges of the semiconductor region 732a, between the channel regions 632a and 632b. Rather than the sharp corners between channel regions illustrated in FIG. 6, in FIG. 7A, the widths of rows 630 and 640 gradually changes between different widths 634, 635, and 636. In the example of FIG. 7A, the width changes are present within the semiconductor regions 732 and 742 between adjacent ones of the channel regions 632 and 642, respectively.

Within a particular transistor 600, the channel region 632 or 642 between the two S/D regions is substantially rectangular. The channel regions 632 and 642 may have even less bending than in the example of FIGS. 4 and 5, due to the smaller width variation between adjacent channel regions and greater granularity in widths along a row. As noted above, reducing the inconsistency in widths within the channel regions 632 and 642 in the channel regions can mitigate the undesired electrical effects compared to prior designs, e.g., the design of FIG. 2.

FIG. 7B illustrates an example implementation of the layout design of FIG. 6 with sources and drains formed along the nanoribbons and a variation of example jog effects, according to some embodiments of the present disclosure. In the example of FIG. 7A, the illustrated channel regions 632 and 642 are rectangular or substantially rectangular, and the curved lines (e.g., the curved lines 750a and 750b) where the width of the channel material 104 or 116 increases or decreases between adjacent channel regions 632 or 642 were along the semiconductor regions 732 or 742 between adjacent channel regions 632 or 642. In other embodiments, the edges of the channel regions 632 and 642 may have a small amount of curving or bending.

FIG. 7B shows an example of such an embodiment. FIG. 7B illustrates the same features as FIG. 7A, discussed above, but the edges along rows 730 and 740 of channel materials 104 and 116 have a different shape. In FIG. 7B, the curved lines along row 730 are indicated by dotted lines. The dotted lines extend along the channel regions, e.g., channel region 744 and 746, and along the semiconductor regions, e.g., the semiconductor region 748.

Various widths at different positions along the channel regions 744 and 746 and the semiconductor region 748 are indicated. The channel region 744, which corresponds to the channel region 632b of width 635, has a width that increases slightly moving from left to right. For example, the width 750 near the left end of the channel region 744 is smaller than the width 752 at the right end of the channel region 744. The semiconductor region 748 between the channel regions 744 and 746 has a width that increases moving from left to right. For example, the width 754 near the left end of the semiconductor region 748 is smaller than the width 756 at the right end of the semiconductor region 748. The difference between the widths 750 and 752 may be less than the difference between the widths 754 and 756, i.e., most of the change in width is within the semiconductor regions between channel regions.

The channel region 746, which corresponds to the channel region 632 of width 636, may have a bowed shape, with a larger width near its center than at its ends. For example, the width 758 near the left end of the channel region 746 may be the same as the width 762 near the right end of the channel region 746. Both of the end widths 758 and 762 may be smaller than the width 760 at the center of the channel region 746, e.g., a midpoint of the channel region 746 in the x-direction.

In general, if a channel region with a larger width (e.g., width 636) is between a pair of other channel regions with smaller widths (e.g., the width 635), the channel region may have a bowed or convex shape, i.e., a shape that curves outward. If a channel region with a smaller width (e.g., width 634) is between a pair of other channel regions with greater widths (e.g., the width 635), the channel region may have a concave shape, i.e., a shape that curves inward. If a channel region with a medium width (e.g., the width 635) is between a pair of channel regions with different widths (e.g., one of width 634, and one of width 636), the channel region may have a shape that increases in the direction of the wider channel regions and decreases in the direction of the larger channel region. The overall width variation in a channel region may be relatively low, e.g., less than 5% of the average or maximum width, less than 3% of the average or maximum width, or less than 1% of the average or maximum width.

The curvature of the channel regions and semiconductor regions of the channel material 116 along row 740 is similar to the curvature of the channel regions and semiconductor regions of the channel material 104 along row 730.

Example Transistors with Different Sets of Widths Along Different Rows

FIGS. 3-7 illustrated rows of the channel materials 104 and 116 that included the same set of widths. In some implementations, an IC device may include rows that include different sets of widths. For example, an IC device may include a first device region that generally includes narrower, lower-power devices and a second device region that generally includes wider, higher-power devices. The different device regions may include different rows of channel material, e.g., a first set of rows with relatively narrow widths, and a second set of rows with relatively wide widths.

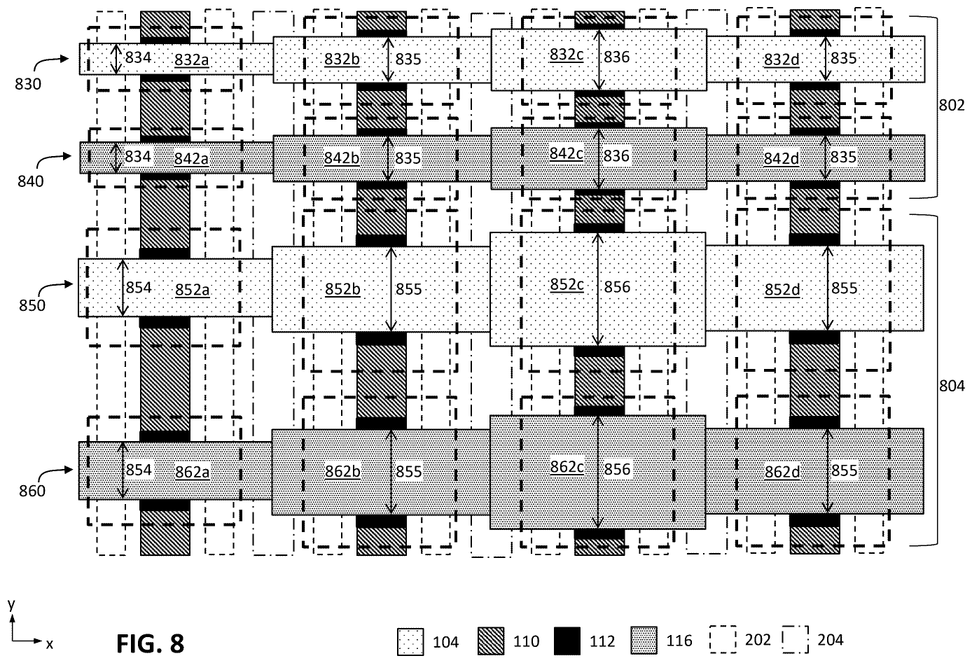

FIG. 8 illustrates an example layout design with reduced jog effects across multiple lines with different sets of widths, according to some embodiments of the present disclosure. FIG. 8 includes four rows of transistors, 830, 840, 850, and 860, formed around corresponding rows of channel material, e.g., rows of nanoribbons.

Each of the rows, and transistors within a given row, are similar to the transistors described with respect to FIG. 6. However, while FIG. 6 included two rows 630 and 640 that had channel regions 632 and 642 of corresponding width, FIG. 8 illustrates two device regions 802 and 804, where the device region 802 includes multiple rows and the device region 804 includes multiple rows. While only two rows are illustrated in each device region 802 and 804, in an implemented IC device, a device region may include many more rows of transistors.

The device region 802 includes rows 830 and 840, where row 830 includes the channel material 104 and row 840 includes the channel materials 116. Row 830 includes channel regions 832a-832d having three different widths, 834, 835, and 836. In this example, row 840 includes channel regions 842a-842d having the same three widths, 834, 835, and 836. The channel regions 832 and 842, and their respective widths 834, 835, and 836, may be similar to the channel regions 632 and 642 and their respective widths 634, 635, and 636, described above.

The device region 804 includes rows 850 and 860, where row 850 includes the channel material 104 and row 860 includes the channel materials 116. Row 850 includes channel regions 852a-852d having three different widths, 854, 855, and 856. In this example, row 860 includes channel regions 862a-862d having the same three widths, 854, 855, and 856. The widths 854, 855, and 856 may be larger than the widths 834, 835, and 836. For example, the largest width (i.e., maximum width) of the widths 854, 855, and 856 in the device region 804 (here, width 856) may be greater than the largest of the widths 834, 835, and 836 (here, width 836). In some embodiments, the smallest width 854 (i.e., the minimum width) in the device region 804 is larger than the largest width 836 in the device region 802. In some embodiments, the smallest width 854 in the device region 804 is equal or substantially equal to the largest width 836 in the device region 802. For example, the width 854 in the device region 804 is within 30%, 20%, 10%, 5%, or some other range of the width 836 in the device region 802.

The smallest width 834 may be in the range of 5-20 nanometers (nm). In a given device region, different widths may have a difference between 1 and 5 nm, in some embodiments. In some embodiments, the difference between widths may be consistent across a device or device region, e.g., the width 835 may be 2 nm greater than 836, and the width 836 2 nm greater than 836. As one example, in the device region 802, the width 834 is 10 nm, the width 836 is 12 nm, and the width 836 is 14 nm. Continuing this example, the width 854 is 14 nm (i.e., equal to the width 836), the width 855 is 16 nm, and the width 856 is 18 nm.

As another example, the width 834 is 12 nm, the width 836 is 15 nm, the width 836 is 17 nm (here, the difference between 835 and 836 is less than the difference between 835 and 834). Continuing this example, the width 854 is 20 nm (greater than the width 836), the width 855 is 23 nm, and the width 856 is 25 nm.

In some embodiments, a given device region may have more than three widths. For example, the device region 802 includes channel regions with widths of 9 nm, 11 nm, 12 nm, 13 nm, and 15 nm, while the device region 804 includes channel regions with widths of 13 nm, 15 nm, 16 nm, and 18 nm. As another example, the device region 802 includes channel regions with widths of 14 nm, 16 nm, 18 nm, and 20 nm, while the device region 804 includes channel regions with widths of 22 nm, 25 nm, 28 nm, and 31 nm.

The device region 804, having generally larger widths than the device region 802, may be a high power and/or high-performance region of an IC device. The device region 802, having generally smaller widths than the device region 802, may be a lower power and/or high-density region of an IC device.

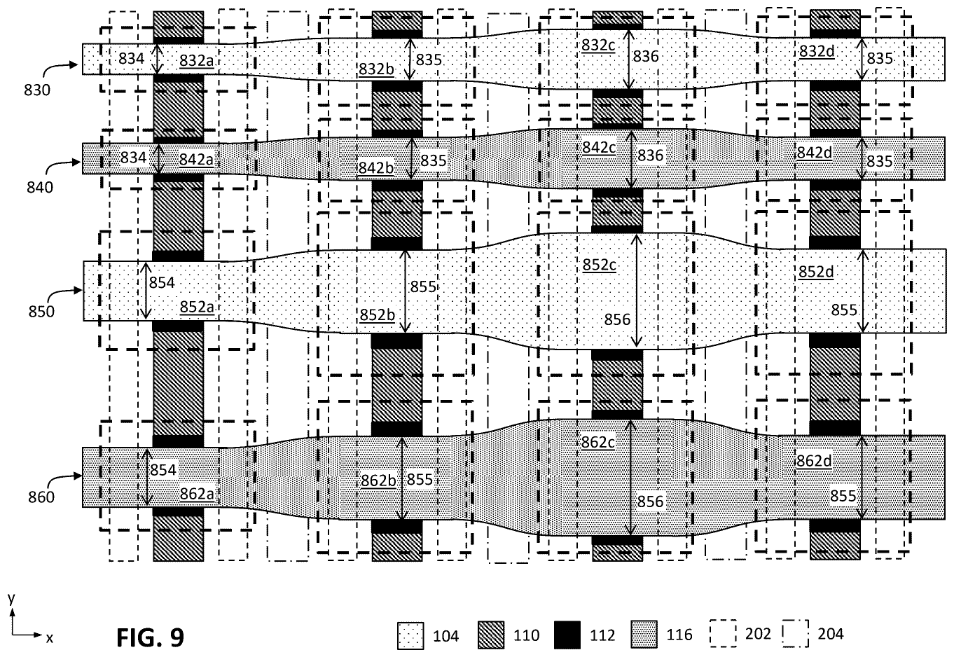

FIG. 9 illustrates an example implementation of the layout design of FIG. 8 with sources and drains formed along the nanoribbons and example jog effects, according to some embodiments of the present disclosure. As described above, the jog effects may result in semiconductor regions between adjacent channel regions, and in some cases the channel regions themselves, to have curved edges. The widths described with respect to FIG. 8 may have some degree of variation across the channel region of a given transistor due to the jog effects. However, because the channel regions are center aligned along their midlines, and because the device regions 802 and/or 804 include three or more available widths, the jog effects within transistors may be minimized.

### Example Devices

The rows of center-aligned nanoribbons with different widths disclosed herein may be included in any suitable electronic device. FIGS. 10-13 illustrate various examples of apparatuses that may include the GAA transistors disclosed herein, which may have been fabricated using the processes disclosed herein.

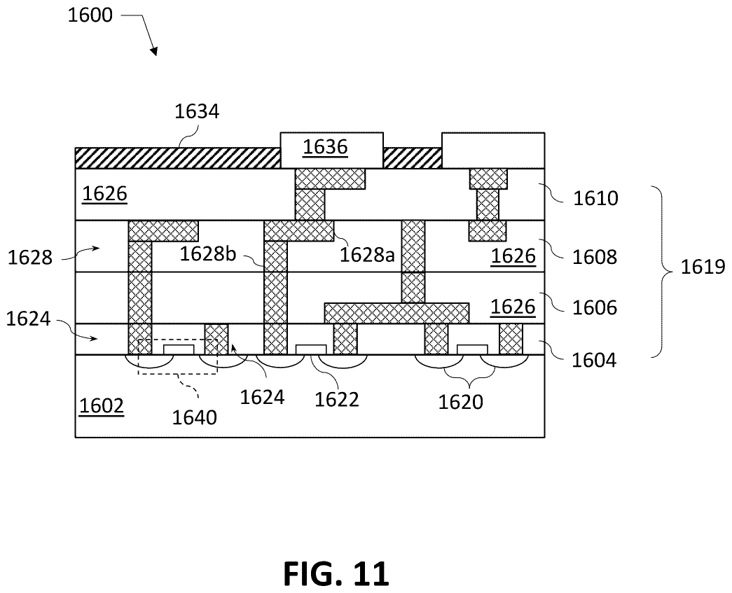

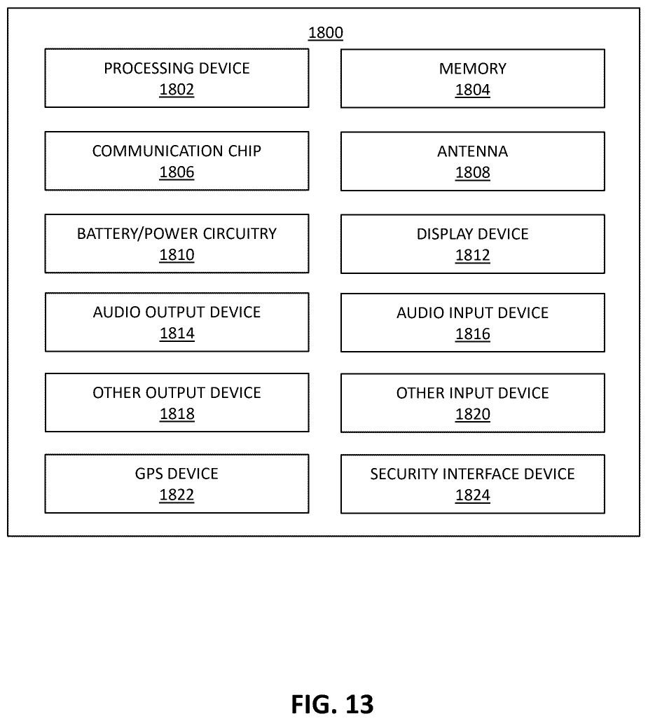

FIGS. 10A and 10B are top views of a wafer and dies that include one or more IC structures including one or more rows of center-aligned nanoribbons with different widths in accordance with any of the embodiments disclosed herein. The wafer 1500 may be composed of semiconductor material and may include one or more dies 1502 having IC structures formed on a surface of the wafer 1500. Each of the dies 1502 may be a repeating unit of a semiconductor product that includes any suitable IC structure (e.g., the IC structures as shown in any of FIGS. 1-9, or any further embodiments of the IC structures described herein). After the fabrication of the semiconductor product is complete (e.g., after manufacture of one or more IC structures with one or more of the transistors as described herein, included in a particular electronic component, e.g., in a transistor or in a memory device), the wafer 1500 may undergo a singulation process in which each of the dies 1502 is separated from one another to provide discrete “chips” of the semiconductor product. In particular, devices that include one or more of the transistors as disclosed herein may take the form of the wafer 1500 (e.g., not singulated) or the form of the die 1502 (e.g., singulated). The die 1502 may include one or more transistors (e.g., one or more of the transistors 1640 of FIG. 11, discussed below) and/or supporting circuitry to route electrical signals to the transistors, as well as any other IC components (e.g., one or more of the non-planar transistors described herein). In some embodiments, the wafer 1500 or the die 1502 may include a memory device (e.g., an SRAM device), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 13) or other logic that is configured to store information in the memory devices or execute instructions stored in the memory array.

FIG. 11 is a cross-sectional side view of an IC device 1600 that may include one or more rows of center-aligned nanoribbons with different widths in accordance with any of the embodiments disclosed herein. The IC device 1600 may be formed on a substrate 1602 (e.g., the wafer 1500 of FIG. 10A) and may be included in a die (e.g., the die 1502 of FIG. 10B). The substrate 1602 may be any substrate as described herein. The substrate 1602 may be part of a singulated die (e.g., the dies 1502 of FIG. 10B) or a wafer (e.g., the wafer 1500 of FIG. 10A).

The IC device 1600 may include one or more device layers 1604 disposed on the substrate 1602. The device layer 1604 may include features of one or more transistors 1640 (e.g., metal-oxide-semiconductor field-effect transistors (MOSFETs)) formed on the substrate 1602. The device layer 1604 may include, for example, one or more source and/or drain (S/D) regions 1620, a gate 1622 to control current flow in the transistors 1640 between the S/D regions 1620, and one or more S/D contacts 1624 to route electrical signals to/from the S/D regions 1620. The transistors 1640 may include additional features not depicted for the sake of clarity, such as device isolation regions, gate contacts, and the like. The transistors 1640 are not limited to the type and configuration depicted in FIG. 11 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

Each transistor 1640 may include a gate 1622 formed of at least two layers, a gate electrode layer and a gate dielectric layer.

The gate electrode layer may be formed on the gate interconnect support layer and may consist of at least one P-type workfunction metal or N-type workfunction metal, depending on whether the transistor is to be a PMOS or an NMOS transistor, respectively. In some implementations, the gate electrode layer may consist of a stack of two or more metal layers, where one or more metal layers are workfunction metal layers and at least one metal layer is a fill metal layer. Further metal layers may be included for other purposes, such as a barrier layer or/and an adhesion layer.

For a PMOS transistor, metals that may be used for the gate electrode include, but are not limited to, ruthenium, palladium, platinum, cobalt, nickel, and conductive metal oxides, e.g., ruthenium oxide. A P-type metal layer will enable the formation of a PMOS gate electrode with a workfunction that is between about 4.9 electron Volts (eV) and about 5.2 eV. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, aluminum carbide, tungsten, tungsten carbide. An N-type metal layer will enable the formation of an NMOS gate electrode with a workfunction that is between about 3.9 eV and about 4.2 eV.

In some embodiments, when viewed as a cross-section of the transistor 1640 along the source-channel-drain direction, the gate electrode may be formed as a U-shaped structure that includes a bottom portion substantially parallel to the surface of the substrate and two sidewall portions that are substantially perpendicular to the top surface of the substrate. In other embodiments, at least one of the metal layers that form the gate electrode may simply be a planar layer that is substantially parallel to the top surface of the substrate and does not include sidewall portions substantially perpendicular to the top surface of the substrate. In other embodiments, the gate electrode may be implemented as a combination of U-shaped structures and planar, non-U-shaped structures. For example, the gate electrode may be implemented as one or more U-shaped metal layers formed atop one or more planar, non-U-shaped layers. In some embodiments, the gate electrode may consist of a V-shaped structure (e.g., when a fin of a FinFET transistor does not have a “flat” upper surface, but instead has a rounded peak).

Generally, the gate dielectric layer of a transistor 1640 may include one layer or a stack of layers, and the one or more layers may include silicon oxide, silicon dioxide, and/or a high-k dielectric material. The high-k dielectric material included in the gate dielectric layer of the transistor 1640 may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer to improve its quality when a high-k material is used.

The IC device 1600 may include one or more rows of center-aligned nanoribbons with different widths at any suitable location in the IC device 1600.

The S/D regions 1620 may be formed within the substrate 1602 adjacent to the gate 1622 of each transistor 1640, using any suitable processes known in the art. For example, the S/D regions 1620 may be formed using either an implantation/diffusion process or a deposition process. In the former process, dopants such as boron, aluminum, antimony, phosphorous, or arsenic may be ion-implanted into the substrate 1602 to form the S/D regions 1620. An annealing process that activates the dopants and causes them to diffuse farther into the substrate 1602 may follow the ion implantation process. In the latter process, an epitaxial deposition process may provide material that is used to fabricate the S/D regions 1620. In some implementations, the S/D regions 1620 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1620 may be formed using one or more alternate semiconductor materials such as germanium or a group III-V material or alloy. In further embodiments, one or more layers of metal and/or metal alloys may be used to form the S/D regions 1620. In some embodiments, an etch process may be performed before the epitaxial deposition to create recesses in the substrate 1602 in which the material for the S/D regions 1620 is deposited.

Electrical signals, such as power and/or input/output (I/O) signals, may be routed to and/or from the transistors 1640 of the device layer 1604 through one or more interconnect layers disposed on the device layer 1604 (illustrated in FIG. 11 as interconnect layers 1606-1610). For example, electrically conductive features of the device layer 1604 (e.g., the gate 1622 and the S/D contacts 1624) may be electrically coupled with the interconnect structures 1628 of the interconnect layers 1606-1610. The one or more interconnect layers 1606-1610 may form an ILD stack 1619 of the IC device 1600.

The interconnect structures 1628 may be arranged within the interconnect layers 1606-1610 to route electrical signals according to a wide variety of designs (in particular, the arrangement is not limited to the particular configuration of interconnect structures 1628 depicted in FIG. 11). Although a particular number of interconnect layers 1606-1610 is depicted in FIG. 11, embodiments of the present disclosure include IC devices having more or fewer interconnect layers than depicted.

In some embodiments, the interconnect structures 1628 may include trench contact structures 1628a (sometimes referred to as “lines”) and/or via structures 1628b (sometimes referred to as “holes”) filled with an electrically conductive material such as a metal. The trench contact structures 1628a may be arranged to route electrical signals in a direction of a plane that is substantially parallel with a surface of the substrate 1602 upon which the device layer 1604 is formed. For example, the trench contact structures 1628a may route electrical signals in a direction in and out of the page from the perspective of FIG. 11. The via structures 1628b may be arranged to route electrical signals in a direction of a plane that is substantially perpendicular to the surface of the substrate 1602 upon which the device layer 1604 is formed. In some embodiments, the via structures 1628b may electrically couple trench contact structures 1628a of different interconnect layers 1606-1610 together.

The interconnect layers 1606-1610 may include a dielectric material 1626 disposed between the interconnect structures 1628, as shown in FIG. 11. The dielectric material 1626 may take the form of any of the embodiments of the dielectric material provided between the interconnects of the IC structures disclosed herein.

In some embodiments, the dielectric material 1626 disposed between the interconnect structures 1628 in different ones of the interconnect layers 1606-1610 may have different compositions. In other embodiments, the composition of the dielectric material 1626 between different interconnect layers 1606-1610 may be the same.

A first interconnect layer 1606 (referred to as Metal 1 or “M1”) may be formed directly on the device layer 1604. In some embodiments, the first interconnect layer 1606 may include trench contact structures 1628a and/or via structures 1628b, as shown. The trench contact structures 1628a of the first interconnect layer 1606 may be coupled with contacts (e.g., the S/D contacts 1624) of the device layer 1604.

A second interconnect layer 1608 (referred to as Metal 2 or “M2”) may be formed directly on the first interconnect layer 1606. In some embodiments, the second interconnect layer 1608 may include via structures 1628b to couple the trench contact structures 1628a of the second interconnect layer 1608 with the trench contact structures 1628a of the first interconnect layer 1606. Although the trench contact structures 1628a and the via structures 1628b are structurally delineated with a line within each interconnect layer (e.g., within the second interconnect layer 1608) for the sake of clarity, the trench contact structures 1628a and the via structures 1628b may be structurally and/or materially contiguous (e.g., simultaneously filled during a dual-damascene process) in some embodiments.

A third interconnect layer 1610 (referred to as Metal 3 or “M3”) (and additional interconnect layers, as desired) may be formed in succession on the second interconnect layer 1608 according to similar techniques and configurations described in connection with the second interconnect layer 1608 or the first interconnect layer 1606.

The IC device 1600 may include a solder resist material 1634 (e.g., polyimide or similar material) and one or more bond pads 1636 formed on the interconnect layers 1606-1610. The bond pads 1636 may be electrically coupled with the interconnect structures 1628 and configured to route the electrical signals of the transistor(s) 1640 to other external devices. For example, solder bonds may be formed on the one or more bond pads 1636 to mechanically and/or electrically couple a chip including the IC device 1600 with another component (e.g., a circuit board). The IC device 1600 may have other alternative configurations to route the electrical signals from the interconnect layers 1606-1610 than depicted in other embodiments. For example, the bond pads 1636 may be replaced by or may further include other analogous features (e.g., posts) that route the electrical signals to external components.

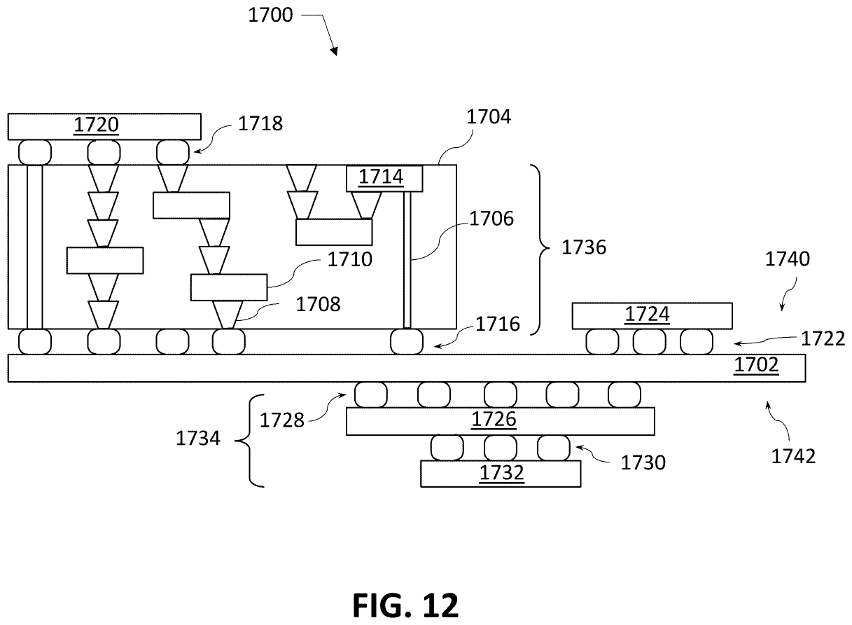

FIG. 12 is a cross-sectional side view of an IC device assembly 1700 that may include components having or being associated with (e.g., being electrically connected by means of) one or more rows of center-aligned nanoribbons with different widths in accordance with any of the embodiments disclosed herein. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742. In particular, any suitable ones of the components of the IC device assembly 1700 may include one or more of the non-planar transistors disclosed herein.

In some embodiments, the circuit board 1702 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate.

The IC device assembly 1700 illustrated in FIG. 12 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702 and may include solder balls (as shown in FIG. 12), male and female portions of a socket, an adhesive, an underfill material, and/or any other suitable electrical and/or mechanical coupling structure.

The package-on-interposer structure 1736 may include an IC package 1720 coupled to an interposer 1704 by coupling components 1718. The coupling components 1718 may take any suitable form for the application, such as the forms discussed above with reference to the coupling components 1716. Although a single IC package 1720 is shown in FIG. 12, multiple IC packages may be coupled to the interposer 1704; indeed, additional interposers may be coupled to the interposer 1704. The interposer 1704 may provide an intervening substrate used to bridge the circuit board 1702 and the IC package 1720. The IC package 1720 may be or include, for example, a die (the die 1502 of FIG. 10B), an IC device (e.g., the IC device 1600 of FIG. 11), or any other suitable component. In some embodiments, the IC package 1720 may include one or more rows of center-aligned nanoribbons with different widths, as described herein. Generally, the interposer 1704 may spread a connection to a wider pitch or reroute a connection to a different connection. For example, the interposer 1704 may couple the IC package 1720 (e.g., a die) to a ball grid array (BGA) of the coupling components 1716 for coupling to the circuit board 1702. In the embodiment illustrated in FIG. 12, the IC package 1720 and the circuit board 1702 are attached to opposing sides of the interposer 1704; in other embodiments, the IC package 1720 and the circuit board 1702 may be attached to a same side of the interposer 1704. In some embodiments, three or more components may be interconnected by way of the interposer 1704.

The interposer 1704 may be formed of an epoxy resin, a fiberglass-reinforced epoxy resin, a ceramic material, or a polymer material such as polyimide. In some implementations, the interposer 1704 may be formed of alternate rigid or flexible materials that may include the same materials described above for use in a semiconductor substrate, such as silicon, germanium, and other group III-V and group IV materials. The interposer 1704 may include metal interconnects 1708 and vias 1710, including but not limited to TSVs 1706. The interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency (RF) devices, power amplifiers, power management devices, antennas, arrays, sensors, and microelectromechanical systems (MEMS) devices may also be formed on the interposer 1704. The package-on-interposer structure 1736 may take the form of any of the package-on-interposer structures known in the art.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 12 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 13 is a block diagram of an example computing device 1800 that may include one or more rows of center-aligned nanoribbons with different widths in accordance with any of the embodiments disclosed herein. For example, any suitable ones of the components of the computing device 1800 may include a die (e.g., the die 1502 (FIG. 10B)) having one or more rows of center-aligned nanoribbons with different widths. Any one or more of the components of the computing device 1800 may include, or be included in, an IC device 1600 (FIG. 11). Any one or more of the components of the computing device 1800 may include, or be included in, an IC device assembly 1700 (FIG. 12).

A number of components are illustrated in FIG. 13 as included in the computing device 1800, but any one or more of these components may be omitted or duplicated, as suitable for the application. In some embodiments, some or all of the components included in the computing device 1800 may be attached to one or more motherboards. In some embodiments, some or all of these components are fabricated onto a single system-on-a-chip (SoC) die.

Additionally, in various embodiments, the computing device 1800 may not include one or more of the components illustrated in FIG. 13, but the computing device 1800 may include interface circuitry for coupling to the one or more components. For example, the computing device 1800 may not include a display device 1812, but may include display device interface circuitry (e.g., a connector and driver circuitry) to which a display device 1812 may be coupled. In another set of examples, the computing device 1800 may not include an audio input device 1816 or an audio output device 1814, but may include audio input or output device interface circuitry (e.g., connectors and supporting circuitry) to which an audio input device 1816 or audio output device 1814 may be coupled.

The computing device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The computing device 1800 may include a memory 1804, which may itself include one or more memory devices such as volatile memory (e.g., dynamic random access memory (DRAM)), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded dynamic random access memory (eDRAM) or spin transfer torque magnetic random-access memory (STT-MRAM).

In some embodiments, the computing device 1800 may include a communication chip 1806 (e.g., one or more communication chips). For example, the communication chip 1806 may be configured for managing wireless communications for the transfer of data to and from the computing device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1806 may implement any of a number of wireless standards or protocols, including but not limited to Institute for Electrical and Electronic Engineers (IEEE) standards including Wi-Fi (IEEE 1402.11 family), IEEE 1402.18 standards (e.g., IEEE 1402.18-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 1402.18 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 1402.18 standards. The communication chip 1806 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1806 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1806 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1806 may operate in accordance with other wireless protocols in other embodiments. The computing device 1800 may include an antenna 1808 to facilitate wireless communications and/or to receive other wireless communications (such as AM or FM radio transmissions).

In some embodiments, the communication chip 1806 may manage wired communications, such as electrical, optical, or any other suitable communication protocols (e.g., the Ethernet). As noted above, the communication chip 1806 may include multiple communication chips. For instance, a first communication chip 1806 may be dedicated to shorter-range wireless communications such as Wi-Fi or Bluetooth, and a second communication chip 1806 may be dedicated to longer-range wireless communications such as GPS, EDGE, GPRS, CDMA, WiMAX, LTE, EV-DO, or others. In some embodiments, a first communication chip 1806 may be dedicated to wireless communications, and a second communication chip 1806 may be dedicated to wired communications.

The computing device 1800 may include a battery/power circuitry 1810. The battery/power circuitry 1810 may include one or more energy storage devices (e.g., batteries or capacitors) and/or circuitry for coupling components of the computing device 1800 to an energy source separate from the computing device 1800 (e.g., AC line power).

The computing device 1800 may include a display device 1812 (or corresponding interface circuitry, as discussed above). The display device 1812 may include any visual indicators, such as a heads-up display, a computer monitor, a projector, a touchscreen display, a liquid crystal display (LCD), a light-emitting diode display, or a flat panel display, for example.

The computing device 1800 may include an audio output device 1814 (or corresponding interface circuitry, as discussed above). The audio output device 1814 may include any device that generates an audible indicator, such as speakers, headsets, or earbuds, for example.

The computing device 1800 may include an audio input device 1816 (or corresponding interface circuitry, as discussed above). The audio input device 1816 may include any device that generates a signal representative of a sound, such as microphones, microphone arrays, or digital instruments (e.g., instruments having a musical instrument digital interface (MIDI) output).

The computing device 1800 may include another output device 1818 (or corresponding interface circuitry, as discussed above). Examples of the other output device 1818 may include an audio codec, a video codec, a printer, a wired or wireless transmitter for providing information to other devices, or an additional storage device.

The computing device 1800 may include another input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 1800 may include a global positioning system (GPS) device 1822 (or corresponding interface circuitry, as discussed above). The GPS device 1822 may be in communication with a satellite-based system and may receive a location of the computing device 1800, as known in the art.

The computing device 1800 may include a security interface device 1824. The security interface device 1824 may include any device that provides security features for the computing device 1800 or for any individual components therein (e.g., for the processing device 1802 or for the memory 1804). Examples of security features may include authorization, access to digital certificates, access to items in keychains, etc. Examples of the security interface device 1824 may include a software firewall, a hardware firewall, an antivirus, a content filtering device, or an intrusion detection device.

The computing device 1800 may have any desired form factor, such as a hand-held or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 1800 may be any other electronic device that processes data.

### Select Examples

The following paragraphs provide various examples of the embodiments disclosed herein.
Example 1 provides a device including a first nanoribbon having a first width; a second nanoribbon having a second width greater than the first width; and a third nanoribbon having a third width greater than the second width; where the first nanoribbon, the second nanoribbon, and the third nanoribbon are centered along a midline that extends perpendicular to the first width, the second width, and the third width.
Example 2 provides the device of example 1, where the second nanoribbon is between the first nanoribbon and the third nanoribbon along the midline.
Example 3 provides the device of example 2, further including a semiconductor region between the first nanoribbon and the second nanoribbon.
Example 4 provides the device of example 3, where a width of the semiconductor region between the first nanoribbon and the second nanoribbon gradually increases in a direction of the second nanoribbon.
Example 5 provides the device of example 2, further including a fourth nanoribbon, where the third nanoribbon is between the second nanoribbon and the fourth nanoribbon along the midline.
Example 6 provides the device of example 5, where the fourth nanoribbon has a fourth width substantially the same as the second width.
Example 7 provides the device of example 6, where the third nanoribbon has a greater width at a midpoint between the second nanoribbon and the fourth nanoribbon than at its ends.
Example 8 provides the device of any preceding example, where the first nanoribbon, the second nanoribbon, and the third nanoribbon have a first carrier type.
Example 9 provides the device of any preceding example, where the first nanoribbon, the second nanoribbon, and the third nanoribbon are stacked over another set of nanoribbons arranged along a line parallel to the midline.
Example 10 provides a device including a first set of semiconductor regions, where different ones of the first set of semiconductor regions have at least three different widths, and central axes through the first set of semiconductor regions are aligned along a first line; a second set of semiconductor regions, where different ones of the second set of semiconductor regions have at least three different widths, and central axes through the second set of semiconductor regions are aligned along a second line parallel to the first line; where a maximum width of the second set of semiconductor regions is greater than a maximum width of the first set of semiconductor regions.
Example 11 provides the device of example 10, where the first set of semiconductors regions have a first carrier type, and the second set of semiconductor regions have a second carrier type different from the first carrier type.
Example 12 provides the device of example 10 or 11, where a minimum width of the second set of semiconductor regions is greater than the maximum width of the first set of semiconductor regions.
Example 13 provides the device of example 10 or 11, where a minimum width of the second set of semiconductor regions is within 20% of the maximum width of the first set of semiconductor regions.
Example 14 provides the device of any of examples 10 through 13, where a gate line extends through a first semiconductor region in the first set and a second semiconductor region in the second set.
Example 15 provides the device of example 14, where the gate line is a first gate line, the device further including a second gate line that extends through a third semiconductor region in the first set and a fourth semiconductor region in the second set.
Example 16 provides the device of example 15, further including a single dummy gate line between the first gate line and the second gate line.
Example 17 provides the device of any of examples 10-16, where a first semiconductor region of the first set of semiconductor regions has a first width across a first gate line, a second semiconductor region of the first set of semiconductor regions has a second width across a second gate line, and a third semiconductor region of the first set of semiconductor regions has a third width across a third gate line, the second width greater than the first width and less than the third width.
Example 18 provides the device of example 17, where the second gate line is between the first gate line and the third gate line.
Example 19 provides a device including a first nanoribbon having a first width; a second nanoribbon having a second width greater than the first width, the first nanoribbon and second nanoribbon are centered along a midline across the first width and the second width; a first source or drain region coupled to a first end of the first nanoribbon; a second source or drain region coupled to a second end of the first nanoribbon, the second end opposite the first end; and a third source or drain region coupled to a first end of the second nanoribbon; where a first distance between the first source or drain region and the second source or drain region is substantially the same as a second distance between the second source or drain region and the third source or drain region.
Example 20 provides the device of example 19, further including a third nanoribbon having a third width greater than the second width, the third nanoribbon centered along the midline across the first width and the second width.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

What is claimed is:

1. A device comprising:
a first nanoribbon having a first width;
a second nanoribbon having a second width greater than the first width; and
a third nanoribbon having a third width greater than the second width;
wherein the first nanoribbon, the second nanoribbon, and the third nanoribbon are centered along a midline that extends perpendicular to the first width, the second width, and the third width.

2. The device of claim 1, wherein the second nanoribbon is between the first nanoribbon and the third nanoribbon along the midline.

3. The device of claim 2, further comprising a semiconductor region between the first nanoribbon and the second nanoribbon.

4. The device of claim 3, wherein a width of the semiconductor region between the first nanoribbon and the second nanoribbon gradually increases in a direction of the second nanoribbon.

5. The device of claim 2, further comprising a fourth nanoribbon, wherein the third nanoribbon is between the second nanoribbon and the fourth nanoribbon along the midline.

6. The device of claim 5, wherein the fourth nanoribbon has a fourth width substantially the same as the second width.

7. The device of claim 6, wherein the third nanoribbon has a greater width at a midpoint between the second nanoribbon and the fourth nanoribbon than at its ends.

8. The device of claim 1, wherein the first nanoribbon, the second nanoribbon, and the third nanoribbon have a first carrier type.

9. The device of claim 1, wherein the first nanoribbon, the second nanoribbon, and the third nanoribbon are stacked over another set of nanoribbons arranged along a line parallel to the midline.

10. A device comprising:
a first set of semiconductor regions, wherein different ones of the first set of semiconductor regions have at least three different widths, and central axes through the first set of semiconductor regions are aligned along a first line;
a second set of semiconductor regions, wherein different ones of the second set of semiconductor regions have at least three different widths, and central axes through the second set of semiconductor regions are aligned along a second line parallel to the first line;
wherein a maximum width of the second set of semiconductor regions is greater than a maximum width of the first set of semiconductor regions.

11. The device of claim 10, wherein the first set of semiconductors regions have a first carrier type, and the second set of semiconductor regions have a second carrier type different from the first carrier type.

12. The device of claim 10, wherein a minimum width of the second set of semiconductor regions is greater than the maximum width of the first set of semiconductor regions.

13. The device of claim 10, wherein a minimum width of the second set of semiconductor regions is within 20% of the maximum width of the first set of semiconductor regions.

14. The device of claim 10, wherein a gate line extends through a first semiconductor region in the first set and a second semiconductor region in the second set.

15. The device of claim 14, wherein the gate line is a first gate line, the device further comprising a second gate line that extends through a third semiconductor region in the first set and a fourth semiconductor region in the second set.

16. The device of claim 15, further comprising a single dummy gate line between the first gate line and the second gate line.

17. The device of claim 10, wherein a first semiconductor region of the first set of semiconductor regions has a first width across a first gate line, a second semiconductor region of the first set of semiconductor regions has a second width across a second gate line, and a third semiconductor region of the first set of semiconductor regions has a third width across a third gate line, the second width greater than the first width and less than the third width.

18. The device of claim 17, wherein the second gate line is between the first gate line and the third gate line.

19. A device comprising:
a first nanoribbon having a first width;
a second nanoribbon having a second width greater than the first width, the first nanoribbon and second nanoribbon are centered along a midline across the first width and the second width;
a first source or drain region coupled to a first end of the first nanoribbon;
a second source or drain region coupled to a second end of the first nanoribbon, the second end opposite the first end; and
a third source or drain region coupled to a first end of the second nanoribbon;
wherein a first distance between the first source or drain region and the second source or drain region is substantially the same as a second distance between the second source or drain region and the third source or drain region.

20. The device of claim 19, further comprising a third nanoribbon having a third width greater than the second width, the third nanoribbon centered along the midline across the first width and the second width.
